(19) United States
(12) Patent Application Publication
(10) Pub. No.: US 2018/0108759 A1
(43) Pub. Date: Apr. 19, 2018

(54) THIN FILM TRANSISTOR, FABRICATION METHOD THEREOF, AND ARRAY SUBSTRATE

(71) Applicant: BOE TECHNOLOGY GROUP CO., LTD., Beijing (CN)

(72) Inventors: Ke WANG, Beijing (CN); Hehe HU, Beijing (CN)

(21) Appl. No.: 15/720,070

(22) Filed: Sep. 29, 2017

(30) Foreign Application Priority Data
Oct. 13, 2016 (CN) 201610894758.3

(51) Int. Cl. H01L 29/66; H01L 29/24; H01L 29/786; H01L 27/12

(52) U.S. Cl. CPC H01L 29/66969; H01L 29/24; H01L 27/1288; H01L 27/1225; H01L 27/127; H01L 29/7869

(57) ABSTRACT

A thin film transistor, a fabrication method thereof, and an array substrate are provided. The fabrication method includes: forming a semiconductor layer and a photoresist layer on a substrate, dividing the substrate, the semiconductor layer and the photoresist layer into a first, second and third regions; performing ladder exposure on the photoresist layer, then developing, completely removing the photoresist layer of the first region and partly removing the photoresist layer of the second region; removing the semiconductor layer of the first region, and forming a pattern including an active region; thinning the photoresist layer: completely removing the photoresist layer of the second region, and partly removing a part of the photoresist layer of the third region; allowing the active region of the second region to be metalized and forming an ohmic contact layer; removing the photoresist layer of the third region; and forming a pattern including a source and a drain.

### CROSS REFERENCE

This application is based upon and claims priority to Chinese Patent Application No. 201610894758.3, filed on Oct. 13, 2016, the entire contents thereof are incorporated herein by reference.

### TECHNICAL FIELD

The present disclosure relates to the field of thin film transistor fabrication technologies, and more particularly to a thin film transistor.

### BACKGROUND

In an array substrate of a display device, a metal oxide thin film transistor (MOS-TFT, a thin film transistor using a metal oxide semiconductor as an active region) is widely used. The etching performance of the metal oxide semiconductor is similar to that of metal materials of a source and a drain. Therefore, when etching and forming the source and the drain, an active region channel (portions of the active region except portions corresponding to the source and the drain) is easily etched.

For this reason, in a related art, an etching stop layer (ESL) is first formed on the channel to protect the channel in the process of subsequently forming the source and the drain. In the process of etching and forming the etching stop layer, the etching environment has a metalization effect on the denuded active region, so that an ohmic contact layer may be formed on a part, of the active region, corresponding to the source and the drain, thereby reducing a contact resistance between the source and the drain. However, this method needs to increase a separate exposure step to form the etching stop layer, which causes a complicated process.

For this reason, another related art is the back channel (BCE) technique, which does not form an etching stop layer, instead technological parameters are controlled when forming the source and the drain to ensure that the source and the drain can be formed without damaging the channel. However, there is no process in this method available for forming the ohmic contact layer, which causes a larger contact resistance between the active region and the source/drain, and thus the product performance is reduced. In particular, for a thin film transistor using aluminum as materials of the source and the drain, poor diffusibility of aluminum further causes increase of the contact resistance.

### SUMMARY

According to an aspect of the present disclosure, there is provided a fabrication method of a thin film transistor, including following steps:

sequentially forming a semiconductor layer and a photoresist layer on a substrate, dividing the substrate and the semiconductor layer and the photoresist layer thereon into a first region, a second region and a third region;

performing ladder exposure on the photoresist layer, then developing, completely removing the photoresist layer of the first region and partly removing the photoresist layer of the second region;

removing the semiconductor layer of the first region, and forming a pattern including an active region;

thinning the photoresist layer: completely removing the photoresist layer of the second region, and partly removing a part of the photoresist layer of the third region;

allowing the active region of the second region to be metalized and forming an ohmic contact layer;

removing the photoresist layer of the third region; and

forming a pattern including a source and a drain through the patterning process.

According to an embodiment of the present disclosure, before the step of sequentially forming a semiconductor layer and a photoresist layer on a substrate, the method further includes the following step: sequentially forming a gate and a gate insulation layer on the substrate.

According to an embodiment of the present disclosure, the step of performing ladder exposure on the photoresist layer includes: performing ladder exposure on the photoresist layer using a halftone mask.

According to an embodiment of the present disclosure, the step of removing the semiconductor layer of the first region includes: removing the semiconductor layer of the first region using an etching process; and/or the step of thinning the photoresist layer comprises: thinning the photoresist layer using an ashing process.

According to an embodiment of the present disclosure, the step of allowing the active region of the second region to be metalized includes: allowing the active region of the second region to be metalized using an ion implantation process.

According to an embodiment of the present disclosure, a molybdenum ion and/or an aluminium ion is implanted in the ion implantation process.

According to an embodiment of the present disclosure, an implantation depth of the ion implantation process is 5˜10 nm; and an acceleration voltage used in the ion implantation process is 5˜10 kV.

According to an embodiment of the present disclosure, a material of the semiconductor layer is a metal oxide semiconductor.

According to an embodiment of the present disclosure, a material of the source and of the drain is aluminum.

According to an embodiment of the present disclosure, the third region is positioned in a middle part of the substrate, the number of the second regions is two, respectively positioned at two sides of the third region, and the first region is positioned at two sides of the two second regions.

According to another aspect of the present disclosure, there is provided with a thin film transistor. The thin film transistor is formed using the fabrication method of a thin film transistor according to the present disclosure. An ohmic contact layer is formed in a part, of an active region of the thin film transistor, coming into contact with a source and a drain, whereas neither the ohmic contact layer nor an etching stop layer is formed in other positions of the active region.

According to another aspect of the present disclosure, there is provided an array substrate, which includes the thin film transistor of the present disclosure.

### BRIEF DESCRIPTION OF THE DRAWINGS

FIG. 1 is a fabrication flowchart of a fabrication method of a thin film transistor according to an embodiment of the present disclosure;

FIG. 2 is a schematic structural diagram of a gate insulation layer formed using a fabrication method of a thin film transistor according to an embodiment of the present disclosure;

FIG. 3 is a schematic structural diagram of a photoresist layer formed using a fabrication method of a thin film transistor according to an embodiment of the present disclosure;

FIG. 4 is a schematic structural diagram of developing the photoresist layer using a fabrication method of a thin film transistor according to an embodiment of the present disclosure;

FIG. 5 is a schematic structural diagram of an active region formed using a fabrication method of a thin film transistor according to an embodiment of the present disclosure;

FIG. 6 is a schematic diagram of the photoresist layer ashed using a fabrication method of a thin film transistor according to an embodiment of the present disclosure;

FIG. 7 is a schematic structural diagram of an ohmic contact layer formed using a fabrication method of a thin film transistor according to an embodiment of the present disclosure;

FIG. 8 is a schematic structural diagram of the photoresist layer removed using a fabrication method of a thin film transistor according to an embodiment of the present disclosure; and

FIG. 9 is a schematic structural diagram of a thin film transistor fabricated using a fabrication method of a thin film transistor according to an embodiment of the present disclosure.

In the drawings, gate 11; gate insulation layer 12; semiconductor layer 2; active region 21; ohmic contact layer 211; source 31; drain 32; photoresist layer 8; substrate 9; first region Q1; second region Q2; third region Q3.

### DETAILED DESCRIPTION

In order that those skilled in the art better understand the technical solution of the present disclosure, in the following the present disclosure is further described in detail with reference to the accompanying drawings and embodiments.

### Embodiment 1

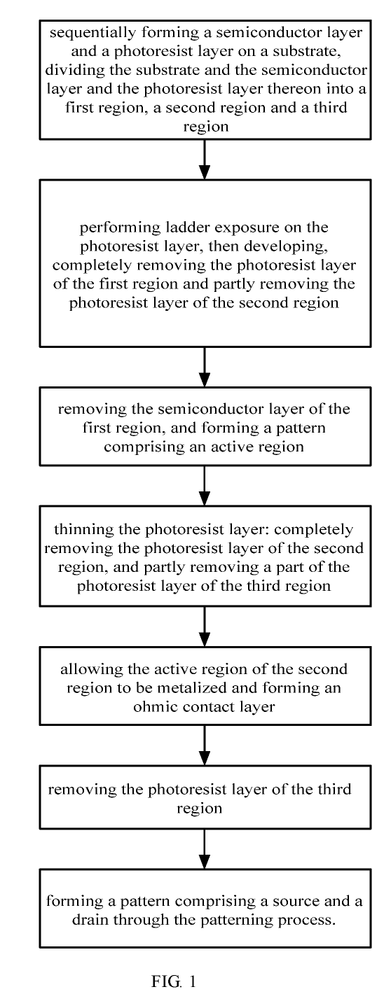

As shown in FIG. 1, this embodiment provides a fabrication method of a thin film transistor, including following steps:

sequentially forming a semiconductor layer and a photoresist layer on a substrate, dividing the substrate and the semiconductor layer and the photoresist layer thereon into a first region, a second region and a third region;

performing ladder exposure on the photoresist layer, then developing, completely removing the photoresist layer of the first region and partly removing the photoresist layer of the second region;

removing the semiconductor layer of the first region, and forming a pattern including an active region;

thinning the photoresist layer: completely removing the photoresist layer of the second region, and partly removing a part of the photoresist layer of the third region; allowing the active region of the second region to be metalized and forming an ohmic contact layer;

removing the photoresist layer of the third region; and

forming a pattern including a source and a drain through the patterning process.

In the fabrication method of the thin film transistor of this embodiment, no etching stop layer is formed, and a ladder exposure technology is used in the step of forming an active region. Therefore, the active region and the ohmic contact layer in the active region may be formed using a single exposure, so that the fabrication process is simplified, a contact resistance between the active region and the source/drain is reduced, and the performance of the thin film transistor is improved.

### Embodiment 2

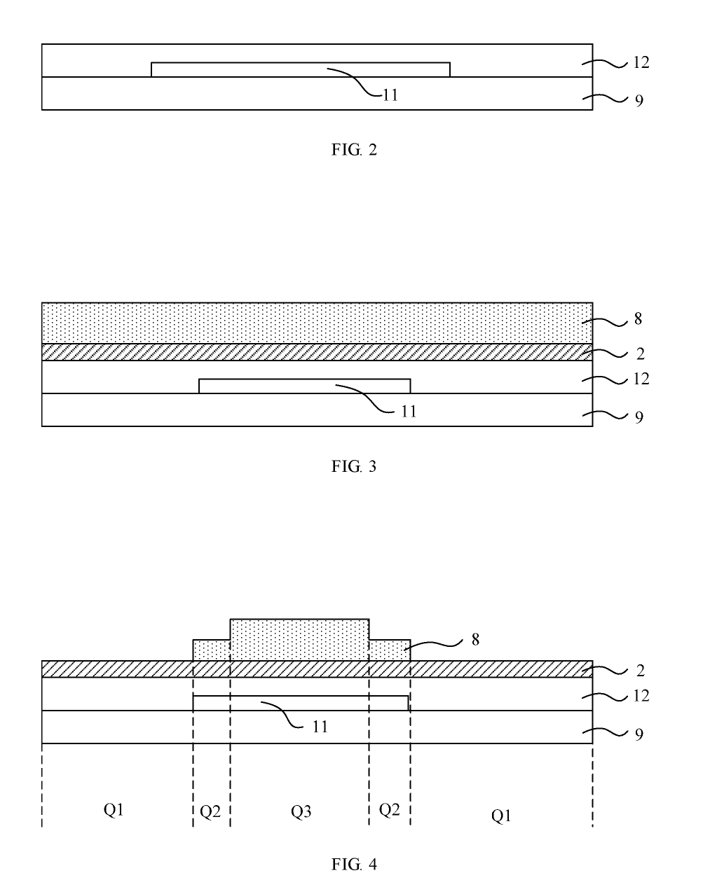

As shown in FIG. 2 to FIG. 9, this embodiment provides a fabrication method of a thin film transistor, which includes following steps:

S201: sequentially forming a gate 11 and a gate insulation layer 12 on a substrate 9. In this embodiment, a third region Q3 is positioned in a middle part of the substrate 9, the number of second regions Q2 is two, respectively positioned at two sides of the third region Q3, and a first region Q1 is positioned at two sides of the two second regions Q2.

That is, the gate 11 (which may further include a gate line and so on) is formed on the substrate 9 through a patterning process, and then the gate insulation layer 12 is deposited. In this way, the structure as shown in FIG. 2 is obtained.

The gate 11 may be made up of materials such as copper, aluminum, molybdenum and so on, and may have a thickness of 200˜500 nm. Before the gate 11 is formed, structures such as a buffer layer (not shown in the figure) may also be formed. The gate insulation layer 12 may be formed using a plasma enhanced chemical vapor deposition (PECVD) process, materials thereof may be silicon dioxide, silicon nitride, or a mixture of silicon dioxide/silicon nitride and so on, and the thickness thereof may be 300˜500 nm.

S202: sequentially forming a semiconductor layer 2 and a photoresist layer 8 on the gate insulation layer 12.

The semiconductor layer 2 is further formed on the substrate 9 upon completing the above step, and then the photoresist layer 8 is coated. In this way, the structure as shown in FIG. 3 is obtained.

The semiconductor layer 2 preferably adopts a metal oxide semiconductor material because the metal oxide semiconductor is more applicable to a back channel technology. Specifically, the metal oxide semiconductor material may be indium zinc tin oxide (ITZO), indium gallium zinc tin oxide (ITGZO) and so on. This is because the two materials are less susceptible to an etching agent used for etching the source 31 and the drain 32. The thickness of the semiconductor layer 2 may be 40˜70 nm.

S203: performing ladder exposure on the photoresist layer 8 using a halftone mask, then developing, and forming the first region Q1 where the photoresist layer 8 is completely removed, the second region Q2 where the photoresist layer 8 is partly reserved, and the third region Q3 where the photoresist layer 8 is completely reserved.

That is, the photoresist layer 8 is exposed using the halftone mask, so that different positions of the photoresist layer 8 are different in exposure degree (namely, ladder exposure). Therefore, after the developing, the photoresist layer 8 of different thicknesses may be reserved in different positions.

Specifically, as shown in FIG. 4, after the developing, the photoresist layer 8 of the first region Q1 (corresponding to other regions except the active region 21 to be formed) is completely removed, so that the semiconductor layer 2 is denuded. However, the photoresist layer 8 having a certain thickness is reserved in the second region Q2 (corresponding to regions where the source 31 and the drain 32 are to be formed). The photoresist layer 8 having a certain thickness is also reserved (for example, completely reserved) in the third region Q3 (corresponding to the channel portion where the active region 21 is to be formed), and the photoresist layer 8 of the third region Q3 is thicker than that of the second region Q2.

S204: removing the semiconductor layer 2 of the first region Q1 using an etching process, and forming a pattern including the active region 21.

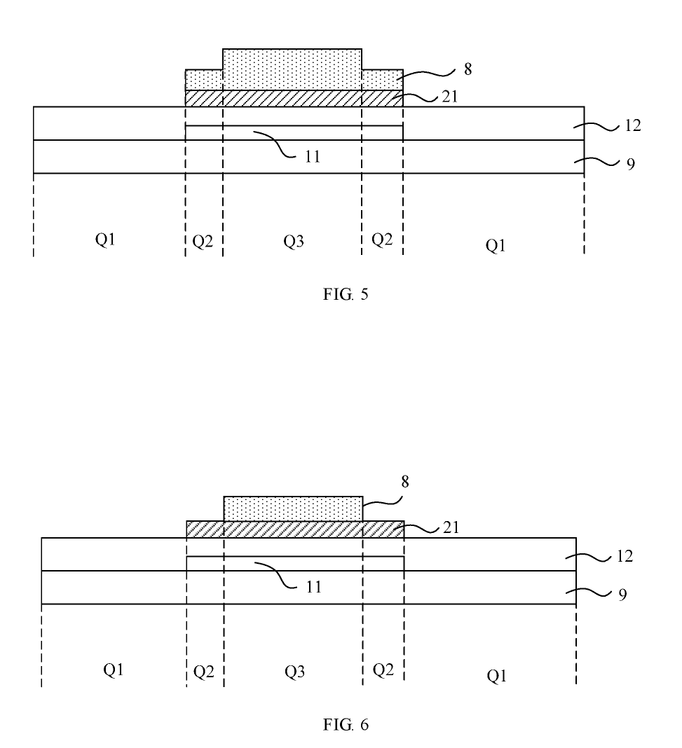

At this moment, the semiconductor layer 2 of the first region Q1 is denuded. Therefore, the semiconductor layer 2 of the first region Q1 may be removed using the etching process, and the remaining semiconductor layer 2 is the active region 21. In this way, the structure as shown in FIG. 5 is formed.

S205: thinning the photoresist layer 8 using an ashing process: completely removing the photoresist layer 8 of the second region Q2, and reserving a part of the photoresist layer 8 of the third region Q3.

That is, the remaining photoresist layer 8 is thinned using the ashing process, so that the photoresist layer 8 of the second region Q2 is completely removed and the photoresist layer 8 having a certain thickness is still reserved in the third region Q3. In this way, the structure as shown in FIG. 6 is obtained.

S206: allowing the active region 21 of the second region Q2 to be metalized using an ion implantation process to form an ohmic contact layer 211.

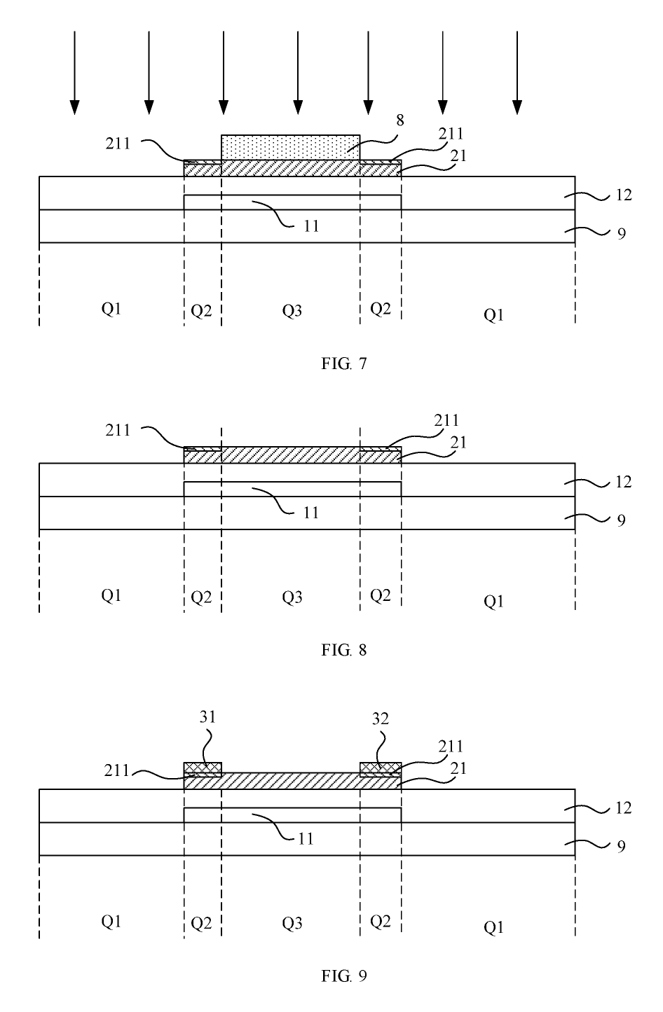

At this moment, the active region 21 of the second region Q2 is denuded. Therefore, metal ions may be introduced into the active region 21 of this region by means of the ion implantation process, so that the active region 21 is metalized to form the ohmic contact layer 211. In this way, the structure as shown in FIG. 7 is obtained.

A molybdenum ion and/or an aluminium ion is preferably implanted in the ion implantation process. An implantation depth of the ion implantation process preferably is 5˜10 nm, and an acceleration voltage used in the ion implantation process preferably is 5˜10 kV. The technological parameters may ensure that the ohmic contact layer 211 having better performance is formed.

S207: removing the photoresist layer 8 of the third region Q3.

The remaining photoresist layer 8 of the third region Q3 is completely removed. In this way, the structure as shown in FIG. 8 is obtained.

Preferably, after the photoresist layer 8 is removed, the active region 21 may be annealed in air or oxygen atmosphere. For example, the active region 21 is annealed at the temperature of 320˜380° C. for one hour to introduce oxygen atoms into the active region 21 so as to improve the performance stability thereof.

S208: forming a pattern including the source 31 and the drain 32 through the patterning process.

That is, structures such as the source 31 (which may further include a data line and the like) and the drain 32 are formed further using the patterning process. In this way, the thin film transistor as shown in FIG. 9 is obtained. The source 31 and the drain 32 are formed in the second region Q2. Therefore, the source 31 and the drain 32 are exactly connected to the active region 21 via the ohmic contact layer 211. The smaller the contact resistance between the active region 21 and the source 31/drain 32 is, the better the performance of the thin film transistor is.

Of course, in different specific application environments, the above source 31 and the drain 32 may further include parts stretching out of the second region Q2 and connecting other structures, for example, parts connecting data lines or pixel electrodes and so on.

Preferably, the material of the source 31 and of the drain 32 may be aluminum, and the thickness thereof may be 200˜500 nm.

As described previously, aluminum is poor in diffusivity. Therefore, when aluminum is used as the source 31 and the drain 32, it has no permeation to the active region 21, which causes a larger contact resistance. Therefore, the source 31 and the drain 32 made of aluminum are more applicable to the present disclosure.

As can be seen, in the above fabrication procedure, the ladder exposure technology is used in the step of forming the active region 21. Therefore, the active region 21 and the ohmic contact layer 211 in the active region 21 may be formed using a single exposure. That is, the ohmic contact layer 211 neither needs using additional exposure technologies nor needs forming an etching stop layer. Therefore, the fabrication method of the thin film transistor of this embodiment is simple in process, the contact resistance between the active region 21 and the source 31/drain 32 is low, and the thin film transistor is good in performance.

If the thin film transistor fabricated using the above processes is the thin film transistor used in an array substrate, steps of forming the passivation layer and the pixel electrode or the like may be proceeded to fabricate the array substrate.

For example, the passivation layer may adopt silicon dioxide, silicon nitride, or a mixture of silicon dioxide/silicon nitride, and the thickness thereof may be 200˜400 nm. The pixel electrode may adopt indium tin oxide (ITO), indium zinc oxide (IZO) and so on, and the thickness thereof may be 40˜70 nm.

In addition, upon completing the fabrication of other structures, final annealing may be proceeded to improve the stability of the thin film transistor and reduce the resistivity of the pixel electrode. For example, annealing may be proceeded in air or oxygen atmosphere at the temperature of 250˜300° C. for about one hour.

### Embodiment 3

This embodiment provides a thin film transistor, which is fabricated using the fabrication method of a thin film transistor according to any one of the above embodiments. Hence, an ohmic contact layer is formed in a part, of the active region of the thin film transistor, coming into contact with the source and the drain, whereas neither the ohmic contact layer nor an etching stop layer is formed in other positions of the active region.

This embodiment further provides an array substrate, which includes the above thin film transistor.

This embodiment further provides a display device, which includes the above array substrate.

Specifically, the display device may be any product or component having a display function, such as a liquid crystal display panel, an electronic paper display, an OLED panel, a mobile phone, a tablet computer, a TV set, a display, a notebook computer, a digital photo frame, a navigation device and so on.

It is to be understood that the foregoing embodiments are merely exemplary embodiments employed to describe the principle of the present disclosure. However, the present disclosure is not limited to this. For those of ordinary skill in the art, various modifications and improvements may be made without departing from the spirit and essence of the present disclosure, and these modifications and improvements are also deemed to be within the scope of protection of the present disclosure.

What is claimed is:

1. A fabrication method of a thin film transistor, comprising following steps:
sequentially forming a semiconductor layer and a photoresist layer on a substrate, dividing the substrate and the semiconductor layer and the photoresist layer thereon into a first region, a second region and a third region;
performing ladder exposure on the photoresist layer, then developing, completely removing the photoresist layer of the first region and partly removing the photoresist layer of the second region;
removing the semiconductor layer of the first region, and forming a pattern comprising an active region;
thinning the photoresist layer, comprising completely removing the photoresist layer of the second region, and partly removing a part of the photoresist layer of the third region;
allowing the active region of the second region to be metalized and forming an ohmic contact layer;
removing the photoresist layer of the third region; and
forming a pattern comprising a source and a drain through the patterning process.

2. The fabrication method of the thin film transistor according to claim 1, wherein before the step of sequentially forming a semiconductor layer and a photoresist layer on a substrate, the method further comprises the following step:
sequentially forming a gate and a gate insulation layer on the substrate.

3. The fabrication method of the thin film transistor according to claim 1, wherein
the step of performing ladder exposure on the photoresist layer comprises: performing ladder exposure on the photoresist layer using a halftone mask.

4. The fabrication method of the thin film transistor according to claim 1, wherein
the step of removing the semiconductor layer of the first region comprises: removing the semiconductor layer of the first region using an etching process; and/or
the step of thinning the photoresist layer comprises: thinning the photoresist layer using an ashing process.

5. The fabrication method of the thin film transistor according to claim 1, wherein the step of allowing the active region of the second region to be metalized comprises:
allowing the active region of the second region to be metalized using an ion implantation process.

6. The fabrication method of the thin film transistor according to claim 5, wherein
a molybdenum ion or an aluminium ion is implanted in the ion implantation process.

7. The fabrication method of the thin film transistor according to claim 6, wherein
an implantation depth of the ion implantation process is 5 nm˜10 nm; and
an acceleration voltage used in the ion implantation process is 5 kV˜10 kV.

8. The fabrication method of the thin film transistor according to claim 1, wherein
a material of the semiconductor layer is a metal oxide semiconductor.

9. The fabrication method of the thin film transistor according to claim 1, wherein
a material of the source and of the drain is aluminum.

10. The fabrication method of the thin film transistor according to claim 1, wherein the third region is positioned in a middle part of the substrate, the number of the second regions is two, respectively positioned at two sides of the third region, and the first region is positioned at two sides of the two second regions.

11. A thin film transistor, wherein
the thin film transistor is formed using the fabrication method of a thin film transistor according to claim 1; and
an ohmic contact layer is formed in a part, of an active region of the thin film transistor, coming into contact with a source and a drain, whereas neither the ohmic contact layer nor an etching stop layer is formed in other positions of the active region.

12. A thin film transistor, wherein
the thin film transistor is formed using the fabrication method of a thin film transistor according to claim 2; and
an ohmic contact layer is formed in a part, of an active region of the thin film transistor, coming into contact with a source and a drain, whereas neither the ohmic contact layer nor an etching stop layer is formed in other positions of the active region.

13. A thin film transistor, wherein
the thin film transistor is formed using the fabrication method of a thin film transistor according to claim 3; and
an ohmic contact layer is formed in a part, of an active region of the thin film transistor, coming into contact with a source and a drain, whereas neither the ohmic contact layer nor an etching stop layer is formed in other positions of the active region.

14. A thin film transistor, wherein
the thin film transistor is formed using the fabrication method of a thin film transistor according to claim 4; and
an ohmic contact layer is formed in a part, of an active region of the thin film transistor, coming into contact with a source and a drain, whereas neither the ohmic contact layer nor an etching stop layer is formed in other positions of the active region.

15. A thin film transistor, wherein
the thin film transistor is formed using the fabrication method of a thin film transistor according to claim 7; and
an ohmic contact layer is formed in a part, of an active region of the thin film transistor, coming into contact with a source and a drain, whereas neither the ohmic contact layer nor an etching stop layer is formed in other positions of the active region.

16. A thin film transistor, wherein
the thin film transistor is formed using the fabrication method of a thin film transistor according to claim 10; and
an ohmic contact layer is formed in a part, of an active region of the thin film transistor, coming into contact with a source and a drain, whereas neither the ohmic contact layer nor an etching stop layer is formed in other positions of the active region.

17. An array substrate, comprising:
the thin film transistor according to claim 12.

18. An array substrate, comprising:
the thin film transistor according to claim 13.

19. An array substrate, comprising:
the thin film transistor according to claim 14.

20. An array substrate, comprising:
the thin film transistor according to claim 16.
